(19) United States
(12) Patent Application Publication
(10) Pub. No.: US 2026/0043832 A1
(43) Pub. Date: Feb. 12, 2026

(54) CONDUCTIVE MEMBRANE FOR TESTING

(71) Applicant: InnoLux Corporation, Miao-Li County (TW)

(72) Inventors: Kuang-Ming FAN, Miao-Li County (TW); Yi-Liang CHEN, Miao-Li County (TW); Chun-Hung CHEN, Miao-Li County (TW)

(21) Appl. No.: 19/262,645

(22) Filed: Jul. 8, 2025

Related U.S. Application Data
(60) Provisional application No. 63/680,705, filed on Aug. 8, 2024.

(30) Foreign Application Priority Data
Mar. 24, 2025 (CN) 202510346792.6

(51) Int. Cl. G01R 1/073; G01R 1/067

(52) U.S. Cl. CPC G01R 1/0735; G01R 1/06761

(57) ABSTRACT

A conductive membrane for testing, including: a circuit structure including a first metal layer and a second metal layer disposed on the first metal layer; a protrusion portion disposed on the circuit structure and protruding from the circuit structure; and an insulating layer disposed surrounding the first metal layer and the second metal layer, wherein the protrusion portion and the second metal layer are overlapped, and at least part of the insulating layer is disposed between the second metal layer and the protrusion portion.

### CROSS-REFERENCE TO RELATED APPLICATIONS

This application claims the benefits of the Chinese Patent Application Serial Number 202510346792.6, filed on Mar. 24, 2025, the subject matter of which is incorporated herein by reference.

This application claims the benefit of filing date of U.S. Provisional Application Ser. No. 63/680,705, filed Aug. 8, 2024 under 35 USC § 119(e)(1).

### BACKGROUND

### Field

The present disclosure relates to a conductive membrane for testing. More specifically, the present disclosure relates to a conductive membrane for testing with a cushioning properties.

### Description of Related Art

A probe card structure or a conductive membrane for testing is usually connected to a printed circuit board (PCB) to provide a force required for planarity well contact during the testing process. However, the previous probe card structure or conductive membrane for testing, due to the lack of internal cushioning design between different metals, are prone to poor durability and rapid wear after contact and collision. In addition, the conductive membrane for wafer testing may cause scratches on wafer.

Therefore, it is desirable to provide a novel probe card structure or a conductive membrane for testing to solve the aforesaid problems.

### SUMMARY

The present disclosure provides a conductive membrane for testing, comprising: a circuit structure comprising a first metal layer and a second metal layer disposed on the first metal layer; a protrusion portion disposed on the circuit structure and protruding from the circuit structure; and an insulating layer disposed surrounding the first metal layer and the second metal layer, wherein the protrusion portion and the second metal layer are overlapped, and at least part of the insulating layer is disposed between the second metal layer and the protrusion portion.

Other novel features of the disclosure will become more apparent from the following detailed description when taken in conjunction with the accompanying drawings.

### BRIEF DESCRIPTION OF DRAWINGS

FIG. 1 is a schematic view of an electrical measurement system comprising a conductive membrane for testing according to one embodiment of the present disclosure.

FIG. 2 is a top schematic view of a conductive membrane for testing according to one embodiment of the present disclosure.

FIG. 3 is a schematic view of an electrical measurement system comprising a conductive membrane for testing according to another embodiment of the present disclosure.

FIG. 4 to FIG. 7 are partial schematic views of conductive membranes for testing according to different embodiments of the present disclosure.

FIG. 8 is a cross-sectional schematic view showing a process for manufacturing a conductive membrane for testing according to one embodiment of the present disclosure.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

The terms, such as “about”, “substantially”, or “approximately”, are generally interpreted as within 10%, 5%, 3%, 2%, 1%, or 0.5% of a given value or range. The quantity given here is an approximate quantity, that is, without specifying “about”, “approximately”, “substantially” and “approximately”, “about”, “approximately”, “substantially” and “approximately” can still be implicitly to convey this meaning. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, what is described as being on the “below” side will become the component on the “above” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

It the present disclosure, the distance, the width, the length and the thickness may be measured by using an optical microscope (OM) or by using a cross-sectional image of a scanning electron microscope (SEM), but the present disclosure is not limited thereto. Furthermore, any two values or directions used for comparison may have a certain error. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

It should be noted that the following embodiments may be implemented by replacing, reorganizing, or mixing features of several different embodiments without departing from the spirit of the present disclosure to implement other embodiments.

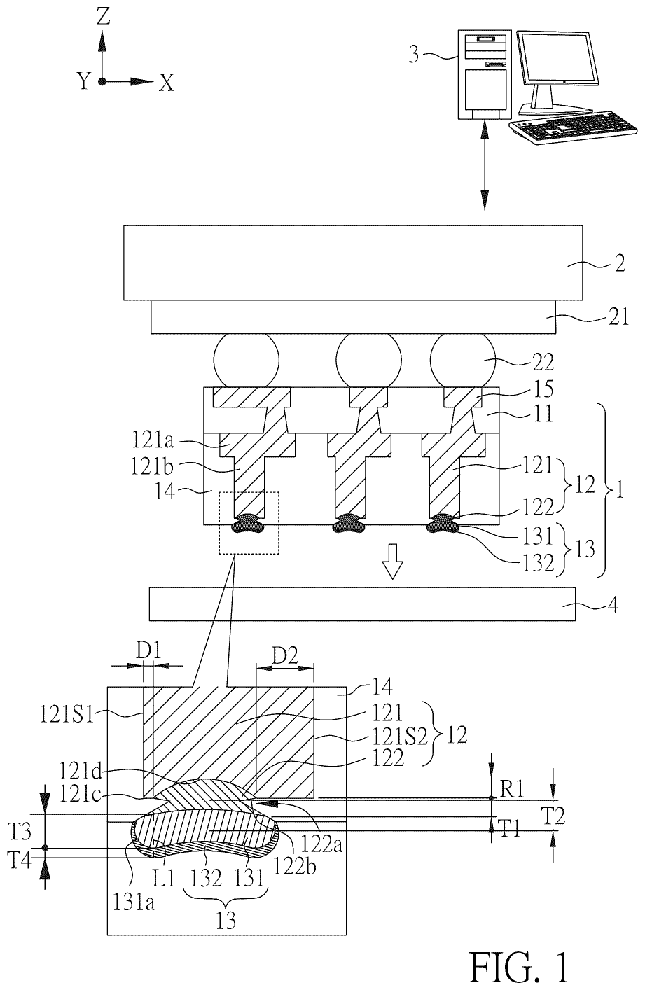

FIG. 1 is a schematic view of an electrical measurement system comprising a conductive membrane for testing according to one embodiment of the present disclosure. In FIG. 1, except for the control device 3, the remaining components are represented by a cross-sectional schematic view.

As shown in FIG. 1, the electrical measurement system of the present disclosure comprises: a conductive membrane for testing 1; a test head 2 with a circuit board 21 formed thereon, wherein the conductive membrane for testing 1 is electrically connected to a circuit board 21 through an electrical connection component 22; and a control device 3 electrically connected to the test head 2. In one embodiment, the electrical connection component 22 may be a solder ball; but the present disclosure is not limited thereto. When the electrical measurement system shown in FIG. 1 is used to detect an object to be tested 4, the control device 3 may control the test head 2 to move toward the object to be tested 4, so that the conductive membrane for testing 1 connected to the test head 2 can contact the object to be tested 4. The control device 3 may provide a detection signal to the test head 2, and then the test head 2 transmits the detection signal to the conductive membrane for testing 1 to detect the object to be tested 4. Then, the obtained detection signal can be transmitted to the test head 2 through the conductive membrane for testing 1, and then to the control device 3.

In one embodiment, the object to be tested 4 may be a semiconductor device, such as a wafer. In another embodiment, the object to be tested 4 may be an electronic device, such as a display device, a sensing device, an antenna device, a touch device, a tiled device or other suitable electronic device, but the present disclosure is not limited thereto. The display device of the present disclosure may be a non-self-luminous display device or self-luminous display device, such as a liquid crystal display, a cholesteric liquid crystal display, an electro-phoretic display, an organic light emitting diode display, and a light emitting diode display, but the present disclosure is not limited thereto. The display device may include a light emitting diode, a light conversion layer or other suitable materials, or a combination thereof, but the present disclosure is not limited thereto. The light emitting diode may comprise, for example, an organic light emitting diode (OLED), a mini LED, a micro LED, a quantum dot LED (which may comprise a QLED or a QDLED), but the present disclosure is not limited thereto. The light conversion layer may comprise a wavelength conversion material and/or a filter material. The wavelength conversion material may comprise, for example, fluorescence, phosphors, quantum dots (QDs), other suitable material or a combination thereof, but the present disclosure is not limited thereto. The sensing device may include, for example, a biometric sensor, a touch sensor, a fingerprint sensor, other suitable sensors, or a combination of the above types of sensors. The antenna device may be, for example, a liquid crystal antenna or other types of antenna, but is not limited thereto. The tiled device may, for example, include a tiled display device or a tiled antenna device, but is not limited thereto. The electronic device may include electronic components, which may include passive components, active components, or a combination thereof, such as capacitors, resistors, inductors, varactor diodes, variable capacitors, filters, diodes, transistors, sensors, micro-electromechanical system components (MEMS), chips, etc., but are not limited thereto. It should be noted that the electronic device disclosed herein may be various combinations of the above devices, but is not limited thereto. The electronic device disclosed herein may be, for example, applied to power modules or semiconductor packaging devices, but is not limited thereto. The electronic device may comprise a system on a chip (SoC), a system in a package (SiP), an antenna in package (AiP) or various combinations of the above devices, but is not limited thereto.

Next, the structure of the conductive membrane for testing 1 of the present disclosure will be described.

In one embodiment, as shown in FIG. 1, the conductive membrane for testing 1 of the present disclosure comprises: a circuit structure 12 comprising a first metal layer 121 and a second metal layer 122 disposed on the first metal layer 121; a protrusion portion 13 disposed on the circuit structure 12 and protruding from the circuit structure 12; and an insulating layer 14 disposed surrounding the first metal layer 121 and the second metal layer 122, wherein the protrusion portion 13 and the second metal layer 122 are overlapped, and at least part of the insulating layer 14 is disposed between the second metal layer 122 and the protrusion portion 13.

In the present disclosure, the conductive membrane for testing 1 may further comprise another insulating layer 11 and a third metal layer 15, wherein the insulating layer 11 and the third metal layer 15 may be disposed under the circuit structure 12, and the third metal layer 15 may be electrically connected to the circuit structure 12. In other embodiments of the present disclosure, even not shown in the figure, the conductive membrane for testing 1 may further comprise other insulating layer and metal layer to achieve the purpose of circuit redistribution and/or further increase the circuit fan-out area.

In the present disclosure, the material of the insulating layer 11 may include, for example, silicon oxide, silicon nitride, silicon oxynitride, ceramic material, glass, silicon wafer or other suitable materials or a combination thereof, but the present disclosure is not limited thereto.

In the present disclosure, the elongation of the insulating layer 14 may be between 20% and 900%. When the elongation of the insulating layer 14 is within the aforesaid range, by disposing at least part of the insulating layer 14 between the second metal layer 122 and the protrusion portion 13, the at least part of the insulating layer 14 can provide an elastomer-like cushioning property, thereby reducing the contact loss impacts on the conductive membrane for testing 1 and improving the durability of the conductive membrane for testing 1. According to some embodiments, the rigidity of the insulating layer 11 may be greater than the rigidity of the insulating layer 14, and the elongation of the insulating layer 11 may be less than that of the insulating layer 14. Thus, the insulating layer 11 can provide support to extend the lifetime of the conductive membrane for testing 1, but the present disclosure is not limited thereto.

In the present disclosure, the elongation of the insulating layer 14 can be measured using a universal testing machine. Herein, the elongation of the insulating layer 14 may refer to the elongation at break, wherein the elongation at break is the total elongation percentage at break, which can be used as an indicator to compare the plasticity of materials. The higher the elongation at break, the greater plasticity of the plastic is. Alternatively, the elongation of the insulating layer 14 may refer to the elongation at yield, wherein the elongation at yield is the elongation ratio at the yield point, which is the longest elongation before permanent deformation occurs.

In the present disclosure, the elongation of the insulating layer 14 may also be measured using other test methods, such as ASTM D3039/D3039M (Standard Test Method for Tensile Properties of Polymer Matrix Composite Materials), ASTM D638 (Standard Test Method for Tensile Properties of Plastics), ASTM D828 (Standard Test Method for Tensile Properties of Paper and Paperboard Using Constant-Rate-of-Elongation Apparatus), ASTM D882 (Standard Test Method for Tensile Properties of Thin Plastic Sheeting) or ISO 37 (Rubber, Vulcanized or Thermoplastic-Determination of Tensile Stress-Strain Properties); but the present disclosure is not limited thereto.

In the present disclosure, the insulating layer 14 may comprise polyimide, photoresist, silane, polymer, epoxy resin, a combination thereof or other suitable materials. In one embodiment, the insulating layer 14 may comprise polyimide. However, the present disclosure is not limited thereto, and the cushioning properties of the elastomer can be provided as long as the elongation of the material of the insulating layer 14 meets the aforementioned conditions.

In the present disclosure, the first metal layer 121, the second metal layer 122 and the third metal layer 15 may have either a single-layer or multilayer structure, and the material may respectively comprise a metal material, a metal oxide material, an alloy thereof or a combination thereof, such as gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), aluminum zinc oxide (AZO) or a combination thereof, but the present disclosure is not limited thereto. In one embodiment of the present disclosure, the material of the first metal layer 121 is copper. In one embodiment of the present disclosure, the material of the second metal layer 122 is nickel.

In the present disclosure, at least part of the insulating layer 14 has a first thickness T1, the second metal layer 122 has a second thickness T2, and a ratio of the first thickness T1 to the second thickness T2 is greater than or equal to 0.1 and less than or equal to 0.5 (0.1≤T1/T2≤0.5). In addition, the second metal layer 122 has a recessed portion 122a, and at least part of the insulating layer 14 is disposed in the recessed portion 122a; wherein the recessed portion 122a is located on a side wall 122b of the second metal layer 122. According to some embodiments, an extension direction of the recessed portion 122a is perpendicular to a normal direction (the Z direction) of the conductive membrane for testing 1, and the width of the recessed portion 122a is gradually changed, which provides the cushioning properties.

In the present disclosure, when at least part of the insulating layer 14 is disposed in the recessed portion 122a on the side wall 122b of the second metal layer 122, since the insulating layer 14 has a certain elongation, at least part of the insulating layer 14 can provide an elastomer-like cushioning property, thereby reducing the contact loss impacts on the conductive membrane for testing 1 and improving the durability of the conductive membrane for testing 1. More specifically, in the normal direction (the Z direction) of the conductive membrane for testing 1, at least part of the second metal layer 122, at least part of the protrusion portion 13 and at least part of the insulating layer 14 are overlapped with each other to form a sandwich structure. That is, at least part of the insulating layer 14 is disposed between at least part of the second metal layer 122 and at least part of the protrusion portion 13.

In the present disclosure, the first thickness T1 of at least part of the insulating layer 14 is a maximum thickness of the at least part of the insulating layer 14 from a surface 121c of the first metal layer 121 to the protrusion portion 13. In the present disclosure, “the first thickness T1 of the at least part of the insulating layer 14” and “the second thickness T2 of the second metal layer 122” respectively refers to a maximum thickness of the at least part of the insulating layer 14 (more specifically, the insulating layer 14 disposed in the recessed portion 122a on the side wall 122b of the second metal layer 122) and a maximum thickness of the second metal layer 122 measured in the normal direction (for example, the Z direction) of the conductive membrane for testing 1.

In the present disclosure, the protrusion portion 13 may comprise a first layer 131 and a second layer 132, the first layer 131 is disposed between the second metal layer 122 and the second layer 132, and a thickness T4 of the second layer 132 is less than a thickness T3 of the first layer 131 (that is, T4<T3). In the present disclosure, “the thickness T4 of the second layer 132” and “the thickness T3 of the first layer 131” respectively refer to the maximum thicknesses of the first layer 131 and the second layer 132 measured in the normal direction (for example, the extension direction of the virtual line L1 along the Z direction) of the conductive membrane for testing 1.

In the present disclosure, the second layer 132 of the protrusion portion 13 may contact a side 131a of the first layer 131 of the protrusion portion 13. In one embodiment of the present disclosure, the second layer 132 of the protrusion portion 13 may at least partially cover the side 131a of the first layer 131 exposed outside the insulating layer 14. In one embodiment of the present disclosure, the second layer 132 of the protrusion portion 13 may completely cover the side 131a of the first layer 131 exposed outside the insulating layer 14.

In the present disclosure, the materials of the first layer 131 and the second layer 132 of the protrusion portion 13 may respectively a metal material which may comprise, for example, gold, silver, copper, palladium, platinum, ruthenium, aluminum, cobalt, nickel, titanium, molybdenum, manganese or an alloy thereof. In one embodiment of the present disclosure, a hardness (HD2) of the second layer 132 of the protrusion portion 13 may be less than a hardness (HD1) of the first layer 131 of the protrusion portion 13 (that is, HD2<HD1). In one embodiment of the present disclosure, a resistivity (R2) of the second layer 132 of the protrusion portion 13 may be less than a resistivity (R1) of the first layer 131 of the protrusion portion 13 (that is, R2<R1). In one embodiment of the present disclosure, the material of the first layer 131 of the protrusion portion 13 may be palladium, and the material of the second layer 132 of the protrusion portion 13 may be gold; however, the present disclosure is not limited thereto.

In the present disclosure, a surface 121c of the first metal layer 121 has a recess 121d, and at least part of the second metal layer 122 is disposed in the recess 121d. In another embodiment of the present disclosure, even not shown in the figure, the surface 121c of the first metal layer 121 may have a plurality of recesses 121d, and be wavy. When the surface 121c of the first metal layer 121 has a recess 121d or is wavy, the second metal layer 122 and the protrusion portion 13 on the first metal layer 121 may also have a recess or be wavy. Thus, the contact effect between the conductive membrane for testing 1 and the object to be tested 4 can be improved.

In the present disclosure, the depth R1 of the recess 121d may be greater than or equal to 0.2 μm and less than or equal to 10 μm (0.2 μm≤R1≤10 μm). In the present disclosure, “the depth R1 of the recess 121d” may refer to the maximum depth of the recess 121d measured in the normal direction (for example, the Z direction) of the conductive membrane for testing 1. According to some embodiments, the hardness of the first layer 131 of the protrusion portion 13 is greater than that of the second metal layer 122. When the hardness of the first layer 131 of the protrusion portion 13 is greater than that of the second metal layer 122, better contact quality during testing can be provided. In addition, when the second metal layer 122 has the recess, it can buffer the stress caused by downward pressure during testing, avoid damage to the conductive membrane for testing 1 or extend the lifetime of the conductive membrane for testing 1, but the present disclosure is not limited thereto. Further, when the hardness of the first layer 131 of the protrusion portion 13 is respectively greater than that of the second metal layer 122 and the hardness of the second layer 132 of the protrusion portion 13, the conductive membrane for testing 1 can have good contact and cushioning properties during measurement, but the present disclosure is not limited thereto.

In the present disclosure, the circuit structure 12 of the conductive membrane for testing 1 may be, for example, a redistribution layer, and comprise at least one conductive layer (for example, the first metal layer 121 and the third metal layer 15) and at least one insulating layer (for example, the insulating layer 11 and the insulating layer 14), to achieve the purpose of circuit redistribution and/or further increase the circuit fan-out area. The purpose of the redistribution layer is to extend a wire to a wider spacing or to reroute a wire to another wire with a different spacing. In addition, in one embodiment of the present disclosure, as shown in FIG. 1, the first metal layer 121 may comprise a conductive bump 121b and a route 121a, the conductive bump 121b is electrically connected to the route 121a, and the second metal layer 122 is disposed on the conductive bump 121b.

In the present disclosure, the positions of the second metal layer 122 and the protrusion portion 13 disposed on the conductive bump 121b of the first metal layer 121 are not particularly limited, and the second metal layer 122 and the protrusion portion 13 may be disposed at the center of the conductive bump 121b or not at the center of the conductive bump 121b. For example, in one embodiment of the present disclosure, as shown in FIG. 1, the second metal layer 122 and the protrusion portion 13 may not be disposed at the center of the conductive bump 121b, that is, in a cross section of the conductive membrane for testing 1, a distance D1 between the second metal layer 122 and the side wall 121S1 of the first metal layer 121 is not equal to another distance D2 between the second metal layer 122 and the side wall 121S2 of the first metal layer 121, but the present disclosure is not limited thereto.

In addition, in FIG. 1, the conductive membrane for testing 1 including three protrusion portions 13 is used as an example, but the present disclosure is not limited thereto. The conductive membrane for testing 1 may have different numbers of protrusion portions 13 according to the test requirement.

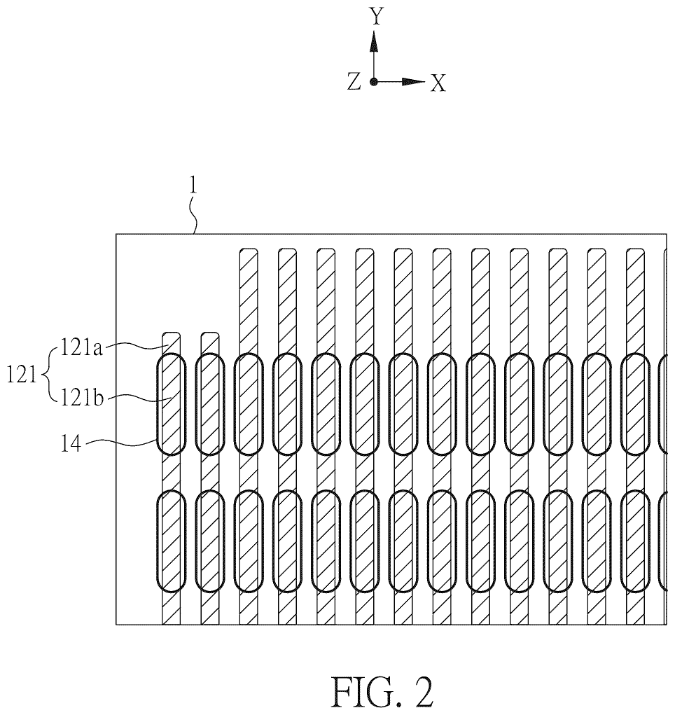

FIG. 2 is a top schematic view of a conductive membrane for testing according to one embodiment of the present disclosure. The cross section of the conductive membrane for testing 1 may be shown in FIG. 1, and will not be described again here. In addition, as shown in FIG. 2, the conductive membrane for testing 1 may comprise a plurality of routes 121a and a plurality of conductive bumps 121b, a portion of the routes 121a and conductive bumps 121b may be electrically connected to each other, and a portion of the routes 121a and the conductive bumps 121b may be electrically insulated from each other. In one embodiment of the present disclosure, a portion of the conductive bumps 121b may also be used as redundant pads; but the present disclosure is not limited thereto.

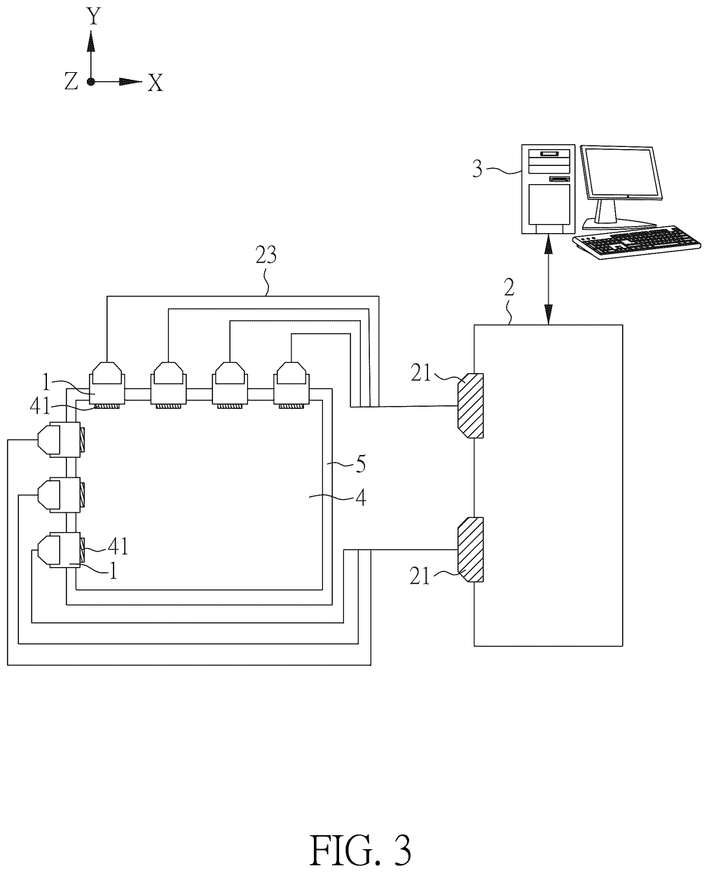

FIG. 3 is a schematic view of an electrical measurement system comprising a conductive membrane for testing according to another embodiment of the present disclosure. In FIG. 3, except for the control device 3, the remaining components are shown in a top view.

As shown in FIG. 3, the electrical measurement system comprises: a conductive membrane for testing 1; a test head 2 with a circuit board 21 formed thereon, wherein the conductive membrane for testing 1 is electrically connected to the circuit board 21 through a conductive line 23; and a control device 3 electrically connected to the test head 2. Herein, the conductive membrane for testing 1 can be referred to that described above and is not described again here.

In the present embodiment, the object to be tested 4 is placed on a testing platform 5 for testing, but the present disclosure is not limited thereto. In addition, the object to be tested 4 may further comprise a test pad 41. When performing the detection, the conductive membrane for testing 1 may be disposed on the test pad 41 and electrically connected to the test pad 41. When the electrical measurement system shown in FIG. 3 is used to test an object to be tested 4, the control device 3 may provide a detection signal to the test head 2, and the test head 2 further transmits the detection signal to the conductive membrane for testing 1 to detect the object to be tested 4. Then, the obtained detection signal is further transmitted to the test head 2 through the conductive membrane for testing 1, and further transmitted to the control device 3. Herein, the object to be tested 4 may be referred to the above, and is not described again here.

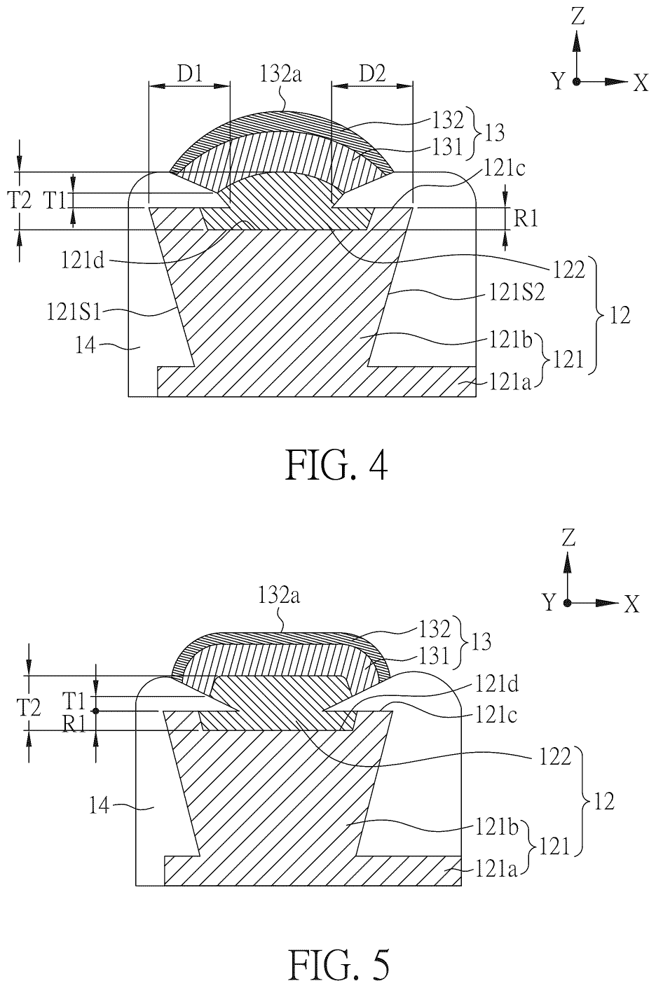

FIG. 4 is a partial schematic view of a conductive membrane for testing according to one embodiment of the present disclosure. The conductive membrane for testing is similar to that shown in FIG. 1, except for the following differences.

As shown in FIG. 4, in the present disclosure, the surface 132a of the second layer 132 of the protrusion portion 13 may be in an arc shape. In addition, the distance D1 between the second metal layer 122 and the side wall 121S1 of the first metal layer 121 may be equal to another distance D2 between the second metal layer 122 and the side wall 121S2 of the first metal layer 121, but the present disclosure is not limited thereto. The remaining features of the conductive membrane for testing of the present disclosure are as described above, and are not described again here.

FIG. 5 is a partial schematic view of a conductive membrane for testing according to one embodiment of the present disclosure. The conductive membrane for testing is similar to that shown in FIG. 1, except for the following differences.

As shown in FIG. 5, in the present disclosure, the surface 132a of the second layer 132 of the protrusion portion 13 may be flat; thus, the contact effect between the conductive membrane for testing 1 and the object to be tested 4 may be improved. The remaining features of the conductive membrane for testing of the present disclosure are as described above, and are not described again here.

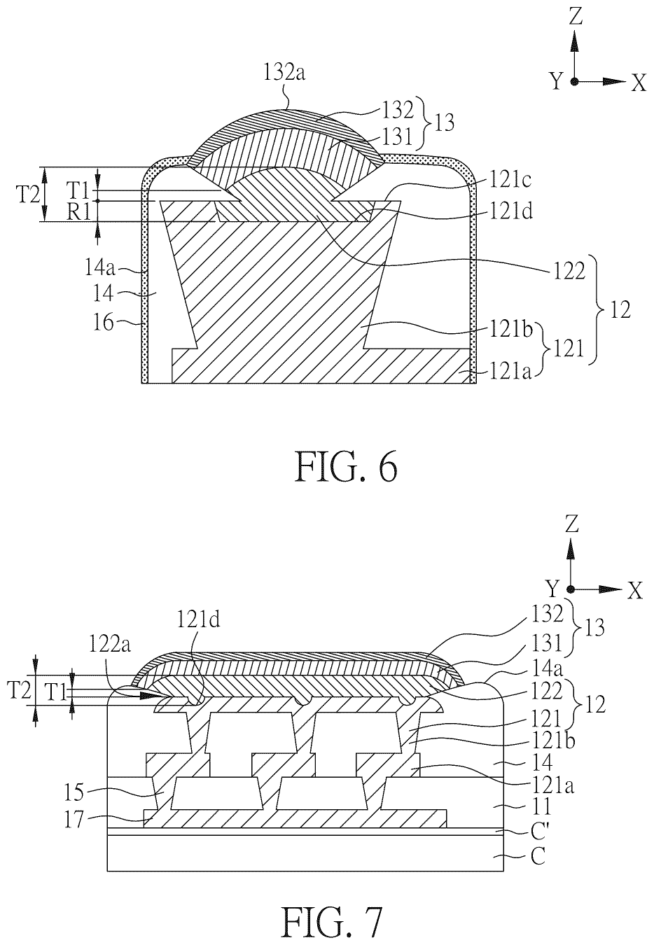

FIG. 6 is a partial schematic view of a conductive membrane for testing according to one embodiment of the present disclosure. The conductive membrane for testing is similar to that shown in FIG. 1, except for the following differences.

As shown in FIG. 6, in the present disclosure, the surface 132a of the second layer 132 of the protrusion portion 13 may be in an arc shape. In addition, the conductive membrane for testing of the present disclosure may further comprise a passivation layer 16 disposed on the exposed surface 14a of the insulating layer 14. More specifically, the passivation layer 16 may be disposed on the surface 14a of the insulating layer 14 not covered by other layers, for example, the surface 14a in contact with the external environment. In the present disclosure, the passivation layer 16 may be used as a water barrier layer, wherein the water vapor transmission rate of the passivation layer 16 may be less than that of the insulating layer 14, thereby reducing the concern that the insulating layer 14 may absorb moisture, further reducing the expansion and contraction issue of the conductive membrane for testing, and thus extending the lifetime of the conductive membrane for testing.

In the present disclosure, the passivation layer 16 may have either a single-layer or a multi-layer structure. In addition, the passivation layer 16 may comprise an organic material, an inorganic material or a combination thereof. For example, the passivation layer 16 may comprise silicon oxide, silicon nitride, silicon oxynitride, epoxy resin, polymer or a combination thereof. In one embodiment of the present disclosure, the passivation layer 16 may be a silicon nitride layer, a silicon oxide layer or a combination thereof. In another embodiment of the present disclosure, the passivation layer 16 may have a laminated structure of inorganic material-organic material-inorganic material, for example, a three-layer structure of silicon nitride-colloid-silicon nitride.

In the present disclosure, the thickness of the passivation layer 16 may be between 10 nm and 5 μm (10 nm≤the thickness≤5 μm). The remaining features of the conductive membrane for testing of the present disclosure are as described above, and are not described again here.

FIG. 7 is a partial schematic view of a conductive membrane for testing according to one embodiment of the present disclosure.

In one embodiment, as shown in FIG. 7, the conductive membrane for testing of the present disclosure comprises: a circuit structure 12 comprising a first metal layer 121 and a second metal layer 122 disposed on the first metal layer 121; a protrusion portion 13 disposed on the circuit structure 12 and protruding from the circuit structure 12; and an insulating layer 14 disposed surrounding the first metal layer 121 and the second metal layer 122; wherein the protrusion portion 13 and the second metal layer 122 are overlapped, and at least part of the insulating layer 14 is disposed between the first metal layer 121 and the protrusion portion 13. According to some embodiments, “A surrounds B” in the present disclosure refers to that the element A contacts at least part of the side of the element B in a cross sectional direction.

In the present disclosure, the first metal layer 121 may comprise a plurality of conductive bumps 121b and a plurality of routes 121a, the conductive bumps 121b are electrically connected to the routes 121a, and the second metal layer 122 is disposed on the conductive bumps 121b. In the present disclosure, at least part of the insulating layer 14 is disposed between adjacent conductive bumps 121b. As described above, the insulating layer 14 has a certain elongation, so at least part of the insulating layer 14 can provide an elastomer-like cushioning property, thereby reducing the contact loss impacts on the conductive membrane for testing 1 and improving the durability of the conductive membrane for testing 1.

In the present disclosure, the three conductive bumps 121b can be electrically connected to each other and are integrated into one on the surface 14a of the insulating layer 14, and then the second metal layer 122 and the protrusion portion 13 are formed thereon. However, the present disclosure is not limited thereto, and a plurality of conductive bumps 121b may be electrically connected to each other and integrated into one on the surface 14a of the insulating layer 14, depending on the requirements.

In the present disclosure, the conductive membrane for testing may further comprise a fourth metal layer 17 disposed under the third metal layer 15 and electrically connected to the third metal layer 15. Herein, the material of the fourth metal layer 17 can be referred to that of the third metal layer 15 mentioned above and is not described again here.

In the present disclosure, the conductive membrane for testing may further comprise a carrier C disposed under the circuit structure 12. When the conductive membrane for testing comprises the carrier C, the support or operability of the conductive membrane for testing can be enhanced. Herein, the elongation of the carrier C may be less than 20%. In addition, the material of the carrier C may comprise glass, quartz, sapphire, ceramics, polycarbonate (PC), polyimide (PI), polypropylene (PP), polyethylene terephthalate (PET), polymethylmethacrylate (PMMA), other suitable material or a combination of the aforesaid materials, but the present disclosure is not limited thereto. When the carrier C comprises an organic material, the elongation of the carrier C can be adjusted by adding filler particles into the organic material layers, wherein the filler particles may include oxides, nitrides or carbides, but the present disclosure is not limited thereto.

In the present disclosure, the conductive membrane for testing may further comprise a buffer layer C′ disposed between the circuit structure 12 and the carrier C. Herein, the material of the buffer layer C′ may comprise, for example, silicon oxide, silicon nitride, silicon oxynitride, other suitable materials or a combination thereof, but the present disclosure is not limited thereto. The remaining features of the conductive membrane for testing of the present disclosure are as described above, and are not described again here.

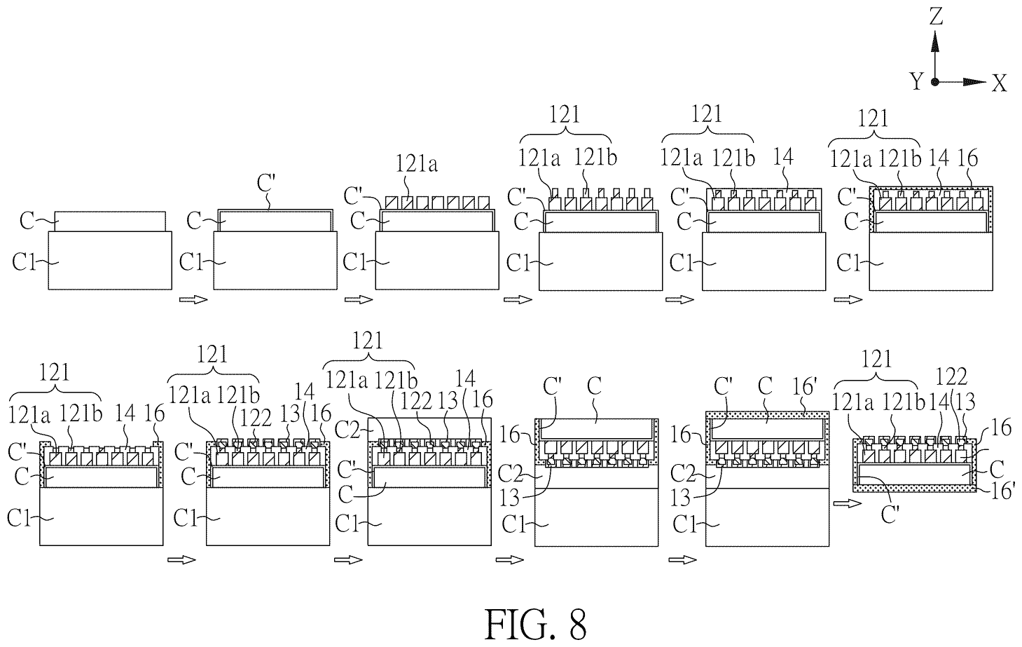

FIG. 8 is a cross-sectional schematic view showing a process for manufacturing a conductive membrane for testing according to one embodiment of the present disclosure.

A temporary substrate C1 is firstly provided, and a carrier C is disposed on the temporary substrate C1. Herein, the material of the temporary substrate C1 may comprise glass, quartz, sapphire, ceramics, polycarbonate (PC), polyimide (PI), polypropylene (PP), polyethylene terephthalate (PET), polymethylmethacrylate (PMMA), other suitable material or a combination thereof, but the present disclosure is not limited thereto. The material of the carrier C is as described above and not described again here. In one embodiment of the present disclosure, the temporary substrate C1 may be a glass substrate, and the carrier C may be a polyimide substrate; but the present disclosure is not limited thereto.

Next, a buffer layer C′ is formed on the carrier C, and the buffer layer C′ may cover all surfaces of the carrier C except the surface facing the temporary substrate C1, but the present disclosure is not limited thereto. In other embodiments of the present disclosure, the buffer layer C′ may only cover the upper surface opposite to the surface facing the temporary substrate C1. Herein, the material of the buffer layer C′ may be as described above and is not described again here. In one embodiment of the present disclosure, the buffer layer C′ may comprise silicon nitride; but the present disclosure is not limited thereto.

Then, a plurality of routes 121a are formed on the buffer layer C′, followed by forming a plurality of conductive bumps 121b on the routes 121a to form the first metal layer 121. Herein, the material of the first metal layer 121 is as described above and not described again here. In one embodiment of the present disclosure, the first metal layer 121 may be a copper layer; but the present disclosure is not limited thereto.

After forming the first metal layer 121, an insulating layer 14 is formed on the first metal layer 121, and the insulating layer 14 is further formed between adjacent routes 121a and adjacent conductive bumps 121b. Herein, the material of the insulating layer 14 is as described above and not described again here. In one embodiment of the present disclosure, the insulating layer 14 may comprise polyimide; but the present disclosure is not limited thereto.

Then, a passivation layer 16 is formed on the insulating layer 14; wherein the passivation layer 16 is formed on the surface of the insulating layer 14 not covered by other layers, for example, the surface in contact with the external environment. In addition, the passivation layer 16 may further be formed on a side surface of the carrier C. More specifically, the passivation layer 16 may further be formed on the buffer layer C′ on the side surface of the carrier C. Herein, the material of the passivation layer 16 may be as described above and is not described again here. In one embodiment of the present disclosure, the passivation layer 16 may have a laminated structure of inorganic material-organic material-inorganic material, for example, a three-layer structure of silicon nitride-colloid-silicon nitride; but the present disclosure is not limited thereto.

After patterning the insulating layer 14 and the passivation layer 16, a second metal layer 122 and a protrusion portion 13 are sequentially formed (for example, including the first layer 131 and the second layer 132 shown in FIG. 1). Herein, the materials of the second metal layer 122 and the protrusion portion 13 are as mentioned above, and not described again here. In one embodiment of the present disclosure, the second metal layer 122 may be a nickel layer, and the protrusion portion 13 may be a palladium-gold stacked metal layer.

Then, a carrier film C2 is formed on the second metal layer 122 and the protrusion portion 13, wherein the material of the carrier film C2 may be referred to the material of the temporary substrate C1 or the carrier C mentioned above, and is not described again here. In one embodiment of the present disclosure, the carrier film C2 may be a polyimide film; but the present disclosure is not limited thereto.

After turning over the structure of the temporary substrate C1, another passivation layer 16′ is formed on the surface of the carrier C. Herein, the material of the passivation layer 16′ may be referred to that of the passivation layer 16 mentioned above and is not described again here. In one embodiment of the present disclosure, the material of the passivation layer 16′ may be similar to that of the passivation layer 16, and may have a laminated structure of inorganic material-organic material-inorganic material (for example, a three-layer structure of silicon nitride-colloid-silicon nitride); but the present disclosure is not limited thereto.

Finally, the temporary substrate C1 and the carrier film C2 are removed to obtain the conductive membrane for testing of the present disclosure. In the present disclosure, the formed conductive membrane for testing comprises a carrier C to improve the support or operability of the conductive membrane for testing. However, in other embodiments of the present disclosure, the conductive membrane for testing may not comprise the carrier C; wherein, the carrier C may be removed, for example, after turning over the structure on the temporary substrate C1 and before forming the passivation layer 16′.

As shown in FIG. 8, in one embodiment of the present disclosure, the passivation layer 16 and the passivation layer 16′ of the conductive membrane for testing may have a laminated structure of inorganic material-organic material-inorganic material, for example, a three-layer structure of silicon nitride-colloid-silicon nitride. Hence, it can prevent organic materials from absorbing water, thus preventing the conductive membrane for testing from being affected by the environment during use, causing poor alignment between the conductive membrane for testing and the object to be tested.

In the present disclosure, the above layers may be formed by any suitable method, such as electroplating, chemical plating, chemical vapor deposition, physical vapor deposition, atomic layer deposition (ALD), sputtering, lamination, coating, photolithography, lift off technology or a combination thereof, but the present disclosure is not limited thereto. The “coating” may be, for example, dip coating, spin coating, roller coating, blade coating, spray coating, or a combination thereof, but the present disclosure is not limited thereto.

In conclusion, in the conductive membrane for testing provided by the present disclosure, at least part of the insulating layer is disposed between the metal layer and the protrusion portion. Therefore, at least part of the insulating layer can provide an elastomer-like cushioning properties, thereby reducing the contact loss impacts on the conductive membrane for testing and improving the durability of the conductive membrane for testing.

The above specific embodiments should be interpreted as merely illustrative and not limiting the rest of the present disclosure in any way.

Although the present disclosure has been explained in relation to its embodiment, it is to be understood that many other possible modifications and variations can be made without departing from the spirit and scope of the disclosure as hereinafter claimed.

1. A conductive membrane for testing, comprising:
a circuit structure comprising a first metal layer and a second metal layer disposed on the first metal layer;
a protrusion portion disposed on the circuit structure and protruding from the circuit structure; and
an insulating layer disposed surrounding the first metal layer and the second metal layer,
wherein the protrusion portion and the second metal layer are overlapped, and at least part of the insulating layer is disposed between the second metal layer and the protrusion portion.

2. The conductive membrane for testing of claim 1, wherein the at least part of the insulating layer has a first thickness, the second metal layer has a second thickness, and a ratio of the first thickness to the second thickness is greater than or equal to 0.1 and less than or equal to 0.5.

3. The conductive membrane for testing of claim 2, wherein the first thickness of the at least part of the insulating layer is a maximum thickness of the at least part of the insulating layer from a surface of the first metal layer to the protrusion portion.

4. The conductive membrane for testing of claim 1, wherein a surface of the first metal layer has a recess, and at least a portion of the second metal layer is disposed in the recess.

5. The conductive membrane for testing of claim 1, wherein the protrusion portion comprises a first layer and a second layer, the first layer is disposed between the second metal layer and the second layer, and a thickness of the second layer is less than a thickness of the first layer.

6. The conductive membrane for testing of claim 5, wherein a material of the first layer of the protrusion portion is palladium.

7. The conductive membrane for testing of claim 5, wherein a material of the second layer of the protrusion portion is gold

8. The conductive membrane for testing of claim 1, wherein the protrusion portion comprises a first layer and a second layer, the first layer is disposed between the second metal layer and the second layer, and the second layer contacts a side of the first layer.

9. The conductive membrane for testing of claim 1, wherein the protrusion portion comprises a first layer and a second layer, the first layer is disposed between the second metal layer and the second layer, and a hardness of the second layer is less than a hardness of the first layer.

10. The conductive membrane for testing of claim 1, wherein the protrusion portion comprises a first layer and a second layer, the first layer is disposed between the second metal layer and the second layer, and a resistivity of the second layer is less than a resistivity of the first layer.

11. The conductive membrane for testing of claim 1, further comprising a passivation layer disposed on an exposed surface of the insulating layer.

12. The conductive membrane for testing of claim 1, wherein an elongation of the insulating layer is between 20% and 900%.

13. The conductive membrane for testing of claim 1, wherein the second metal layer has a recessed portion, and the at least part of the insulating layer is disposed in the recessed portion.

14. The conductive membrane for testing of claim 13, wherein the recessed portion is located on a side wall of the second metal layer.

15. The conductive membrane for testing of claim 1, wherein the first metal layer comprises a conductive bump and a route, the conductive bump is electrically connected to the route, and the second metal layer is disposed on the conductive bump.

16. The conductive membrane for testing of claim 1, further comprising another insulating layer disposed under the circuit structure, wherein a rigidity of the another insulating layer is greater than a rigidity of the insulating layer.

17. The conductive membrane for testing of claim 16, wherein an elongation of the another insulating layer is less than an elongation of the insulating layer.

18. The conductive membrane for testing of claim 1, wherein the insulating layer comprises polyimide, photoresist, silane, polymer, epoxy resin or a combination thereof.

19. The conductive membrane for testing of claim 1, wherein a material of the first metal layer is copper.

20. The conductive membrane for testing of claim 1, wherein a material of the second metal layer is nickel.
